(19) United States
(12) Patent Application Publication
(10) Pub. No.: US 2014/0087180 A1
(43) Pub. Date: Mar. 27, 2014

(54) EASILY RELEASABLE ADHESIVE FILM

(71) Applicants: Mitsunori Maruyama, Saitama (JP); Yasuo Kuriyama, Saitama (JP)

(72) Inventors: Mitsunori Maruyama, Saitama (JP); Yasuo Kuriyama, Saitama (JP)

(73) Assignee: Kimoto Co., Ltd., Saitama (JP)

(21) Appl. No.: 14/123,266

(22) PCT Filed: May 21, 2012
(86) PCT No.: PCT/JP2012/062969

§ 371 Date: Dec. 2, 2013

(30) Foreign Application Priority Data
Jun. 2, 2011 (JP) 2011123958

(51) Int. Cl. H01L 21/683

(52) U.S. Cl. CPC H01L 21/6836
USPC 428/336; 428/352

(57) ABSTRACT

To provide an easily releasable adhesive film that can be easily released from an object, to which the film has been bonded, after processing and that does not deform or damage the object when released therefrom. This easily releasable adhesive film is configured by laminating, in the following order, a first film that is thermally shrinkable (a shrinkable film), an adhesive layer that contains a reactive oligomer together with an adhesive, a second film that is not thermally shrinkable (a non-shrinkable film), and an easily releasable adhesive layer. The reactive oligomer is contained in the adhesive layer in an amount of 12 to 130 parts by weight (inclusive) relative to 100 parts by weight of the adhesive. It is preferable that the easily releasable adhesive layer is configured as an easily releasable adhesive layer that is thermally curable/releasable and contains a reactive oligomer together with an adhesive. It is also preferable that the first film has a shrinkage of 50-90% (inclusive) in the main shrinkage direction at 120° C.

This application is a U.S. national phase filing under 35 U.S.C. §371 of PCT Application. No. PCT/JP2012/062969, filed on May 21, 2012.

### TECHNICAL FIELD

The present invention relates to an easily releasable adhesive film. It particularly relates to an easily releasable adhesive film suitably used as a temporary fixing sheet when processing an object like a semiconductor material, etc., to which the film is bonded.

### BACKGROUND ART

In recent years, there have been increasing demands for semiconductor materials, such as ceramic capacitors, silicon wafers and glass wafers, to be thinner and lighter in weight. For example, in a silicon wafer, which is a semiconductor material, the thickness is designed to be 100 μm or less in more and more cases. Such a thin film wafer is very fragile and easy to be broken. Therefore, to prevent breaking of a thin film wafer as such during processing, a method of attaching an adhesive film having an easily releasable property to the wafer for temporarily fixing, performing processing, such as polishing and dicing, on the temporarily fixed wafer, then, decreasing an adhesive force of the adhesive film by adding light, heat or other external energy to remove it from the wafer has been adopted.

As such an adhesive film, for example, an easily releasable adhesive film formed by laminating, a shrinkable film, an adhesive layer composed of a general-purpose adhesive, non-shrinkable film and an adhesive layer in this order has been proposed (the patent document 1). In an easily releasable adhesive film as such, the shrinkable film shrinks as a result of heating when removing it from an object, to which the easily releasable adhesive film has been bonded, and the opposite side of the object-contacting side of the adhesive film curls to be a concave curve thereby. Consequently, an area contacting with the object decreases, which helps easy releasing of the adhesive film.

### RELATED ART DOCUMENTS

### Patent Documents

Patent Document 1: Japanese Unexamined Patent Publication (Kokai) No. 2000-129227

### SUMMARY OF THE DISCLOSED SUBJECT MATTER

In the easily releasable adhesive film of the technique in the patent document 1, it is true that releasing from an object is considered to be made easy by heating a shrinkable film so as to shrink and deform it. However, in the patent document 1, there is few explanation on an adhesive layer for bonding the shrinkable film and a non-shrinkable film, and there is not a design thought on an adhesive layer. It is because it does not refer to anything other than use of a general-purpose adhesive.

Accordingly, in the technique in the patent document 1, disadvantages as explained below possibly arise depending on a use condition of the adhesive film. For example, when heating the adhesive film, the adhesive layer hinders the shrinking reaction of the shrinkable film and it results in hindering easy removal from the object in some cases. When trying to remove such adhesive film from an object forcedly, the object ends up being deformed or broken. Or detachment occurs at a boundary face of the adhesive layer and the non-shrinkable film and it cannot work as an adhesive in some cases.

According to an aspect of the present invention, there is provided an easily releasable adhesive film which can be easily released from an object, to which the film has been bonded, after processing and does not deform or damage the object when released therefrom.

The present inventors found that an easily releasable adhesive film, which can be easily released from an object, to which the film has been bonded, after processing and does not deform or damage the object when released therefrom, can be obtained by combining a thermally shrinkable first film with an adhesive layer formed by a specific material, and attained the present invention.

The easily releasable adhesive film of the present invention is configured by laminating a first film that is thermally shrinkable (a shrinkable film), an adhesive layer that contains a reactive oligomer together with an adhesive, a second film that is not thermally shrinkable (a non-shrinkable film), and an easily releasable adhesive layer in this order. Particularly, it is characterized in that a reactive oligomer is contained in an amount of 12 parts by weight or more and 130 parts by weight or less in the adhesive layer with respect to 100 parts by weight of the adhesive.

A temporary fixing sheet of the present invention is used by being bonded to an object when processing the object and characterized by being configured by the easily releasable adhesive film of the present invention.

The present invention includes the following modes.
(1) The adhesive layer may be formed to have a thickness of 0.5 μm or more and 10 μm or less.
(2) The easily releasable adhesive layer may be configured by a thermosetting and releasable-type easily releasable adhesive layer containing a reactive oligomer together with an adhesive.
(3) The reactive oligomer may contain at least a urethane acrylate type oligomer. As a urethane acrylate type oligomer, those having a weight average molecular weight of 300 or more and 30,000 or less may be used.
(4) As the first film, those having a shrinkage of 50% or greater and 90% or less in a main shrink direction at 120° C. may be used. As the first film, those having a shrinkage of 10% or less in directions other than the main shrink direction at 120° C. may be used.
(5) As the second film, those having a shrinkage of less than 10% at 120° C. may be used.

Since the easily releasable adhesive film of the present invention is configured by combining an adhesive layer containing a reactive oligomer in a specific amount with a thermally shrinkable first film, it can be easily released from an object, to which the film has been bonded, only by applying heat to the object after completing processing and it does not deform or damage the object when released therefrom. Therefore, the easily releasable adhesive film of the present invention can be used suitably as a processing member (for example, a temporary fixing sheet) for a semiconductor material, etc., which is an example of an object to which the film is bonded.

### EXEMPLARY MODE FOR CARRYING OUT THE DISCLOSED SUBJECT MATTER

The easily releasable adhesive film of the present invention is characterized by being configured by laminating a thermally shrinkable first film (hereinafter, also simply referred to as “shrinkable film”), an adhesive layer containing an adhesive and a reactive oligomer, a second film which is not thermally shrinkable (hereinafter, also simply referred to as “a non-shrinkable film”) and an easily releasable adhesive layer in this order. Below, embodiment(s) of the respective components will be explained.

A shrinkable film used in the present invention is not particularly limited as far as it is a film which shrinks by heat (in other words, thermally shrinkable), however, those which shrink at least in uniaxial direction when heated are preferably used. It means those which “shrink at least in uniaxial direction” may be used, namely, in addition to those which shrink only in uniaxial direction (for example, in the MD direction), those which exhibit shrinkage mainly in uniaxial direction but also exhibit collaterally shrinkage in other direction from that uniaxial direction (for example, biaxial directions (TD direction) being orthogonal to one direction) may be also used. Note that, in the present embodiment, an exhibited main shrinking direction (uniaxial direction) is also referred to as “a main shrink direction”. Also, a shrinkable film may be a single layer product or a multilayer product configured by a plurality of layers. As a multilayer product, other than multilayer products of shrinkage films, multilayer products including a later-explained non-shrinkable film may be also used as long as a shrinkage ratio of the entire multilayer product can be adjusted to be in a later-explained range.

When applying heat to the easily releasable adhesive film of the present invention provided with such a shrinkable film, the shrinkable film shrinks to strain a later-explained non-shrinkable film and, thereby, the entire easily releasable adhesive film including the easily releasable adhesive layer can be easily released from an object.

The shrinkable film used in the present invention has a shrinkage in the main shrink direction (explained above) of preferably 50% or more, more preferably 70% or more and preferably 90% or less. By combining a shrinkable film having a properly adjusted shrinkage with an adhesive film formed by a later-explained specific material, the easily releasable adhesive film of the present invention can be easily released from an object even when used for a thinner and downsized object, and the object is not deformed or damaged.

A shrinkable film used in the present invention has a shrinkage in a direction, other than the main shrink direction of preferably 10% or less and more preferably 5% or less.

Note that, in the present embodiment, “a shrinkage” is what obtained by calculating based on a size change before and after heating the shrinkable film at 120° C. (refer to the calculation formula below).

Shrinkage(%)=[{(Size in Evaluation Direction Before Heating)−(Size in Evaluation Direction After Heating)}/(Size in Evaluation Direction Before Heating)]×100 [Calculation Formula]

The shrink properties of the shrinkable film can be obtained, for example, by performing uniaxial stretching on a film extruded from an extruder.

As a shrinkable film as such, for example, a uniaxial-stretched film formed by one or more kinds of resins selected from polyethylene terephthalate and other polyesters, polyethylene, polypropylene and other polyolefin, polynorbornene, polyimide, polyimide, polyurethane, polystyrene, polyvinylidene chloride, polyvinyl chloride, etc. Among them, in terms of being excellent in coating workability of a later explained adhesive layer coating liquid of an adhesive layer, uniaxial-stretched films formed by a polyester-type resin, polyethylene, polypropylene, polynorbornene and other polyolefin-type resins (including alicyclic polyolefin-type resins), and polyurethane-type resins are preferable.

A thickness of a shrinkable film is not particularly limited and may be suitably selected by balancing with a later-explained non-shrinkable film. Preferably, it is 5 μm to 300 μm, more preferably 10 μm to 100 μm. When the thickness of the shrinkable film is 300 μm or less, a decline of processing accuracy of an object can be prevented. Also, when the thickness is more than 5 μm, release from an object after heating can become easy.

To improve adhesiveness with a contacting layer and to distinguish an existence of an adhered easily releasable adhesive film, a surface of the shrinkable film may be subjected to a well-known treatment, for example, a plasma treatment, corona discharge treatment, far-ultraviolet irradiation treatment, sandblast treatment, chrome chromic acid treatment, alkali treatment, ozone exposure, flame exposure, high-voltage electric shock exposure, ionizing radiation processing, and other chemical or physical treatments, and coating processing, such as formation of an undercoating easily adhesive layer and a coloring layer, etc.

The adhesive layer used in the present invention is provided for the purpose of bonding a shrinkable film and a non-shrinkable film. The adhesive layer used in the present invention should not cause cohesion failure even when the shrinkable film shrinks by heating and have to make the shrinkable film follow the non-shrinkable film.

The adhesive layer used in the present invention contains at least an adhesive and a reactive oligomer.

As an adhesive, for example, general purpose adhesives, such as a rubber-type, acryl-type, vinyl alkyl ether-type, silicon-type, polyimide-type, polyurethane-type, polyester-type, polyether-type and styrene-diene block copolymer-type, and creep characteristics improved-type adhesives obtained by blending a hot-melt resin having a melting point of about 200° C. or lower in those general-purpose adhesives, etc. may be mentioned. These adhesives may be used alone or in combination of a plurality of kinds.

In the present invention, as a material for configuring an adhesive layer, not only an adhesive but also a reactive oligomer is used together. Thereby, the reactive oligomer initiates a polymerizing reaction due to heating and polymerized (polymerizing reaction of a reactive oligomer). The polymerizing reaction of the reactive oligomer is provoked between reactive oligomers and between a reactive oligomer and an adhesive. Consequently, shrink of a shrinkable film as well as sufficient shrink of an adhesive layer are caused, which gives a property of being easily released from an object. Particularly, by using a shrinkable film having a specific shrinkage together, it becomes possible to release it from an object furthermore easily without deforming or damaging the object also when processing (dicing, etc.) an object, which had been made to be thinner and smaller.

A blending amount of the reactive oligomer in the adhesive layer is not particularly limited as long as the effects above can be brought out. To take an example, it is as below.

A reactive oligomer has to be contained in an amount of 12 parts by weight or more, preferably 15 parts by weight or more and furthermore preferably 40 parts by weight or more with respect to 100 parts by weight of an adhesive. When a content of the reactive oligomer is 12 parts by weight or more, it is possible to effectively prevent hindering of the shrink effect of the shrinkable film when heated. As a result, release from an object can be furthermore easy, and deform and damage of the object can be prevented.

The reactive oligomer has to be contained in an adhesive layer in an amount of 130 parts by weight or less, preferably 120 parts by weight or less, and more preferably 70 parts by weight or less with respect to 100 parts by weight of the adhesive. When the content of the reactive oligomer is 130 parts by weight or less, detachment at a boundary face of the adhesive layer and the non-shrinkable film can be prevented effectively when releasing the easily releasable adhesive film from an object, and it can keep functioning as an easily releasable adhesive film.

In the present embodiment, a particularly preferably content (optimal range) of the reactive oligomer contained in the adhesive layer is 40 parts by weight or more and 70 parts by weight or less. By combining an adhesive layer, wherein a content of the reactive oligomer is optimized as above, with a shrinkable film having a specific shrinkage, when releasing the easily releasable adhesive film from an object after heating, a contact area of the easily releasable adhesive film and the object decreases to be nearly zero. As a result, even without a special work of pulling an edge portion of the easily releasable adhesive film with a hand, etc., the easily releasable adhesive film is released by itself from the object, so that release of the easily releasable adhesive film becomes extremely easy.

In the present invention, “a reactive oligomer” means low-molecular-weight compounds and oligomers having two or more photopolymerizable carbon-carbon double bonds in a molecule, which can become a three-dimensional reticulate structure due to a thermal treatment.

As a polyfunctional acrylate-type compound, for example, trimethylolpropane triacrylate, tetramethylol methane tetraacrylate, pentaerythritol triacrylate, pentaerythritol tetraacrulate, dipentaerythritol monohydroxy pentaacrylate, dipentaerythritol hexaacrylate or 1,4-butylene glycol diacrylate, 1,6-hexanediol diacrylate, polyethylene glycol diacrylate, oligoester acrylate, urethane acrylate-type oligomer, polyester acrylate-type oligomer, etc. may be mentioned. Particularly, among them, in terms of adhesiveness, a urethane acrylate-type oligomer is preferably used.

A urethane acrylate-type oligomer is a thermosetting compound having at least two carbon-carbon double bonds, and those obtained as a result that a isocyanate-terminated urethane prepolymer (obtained by bringing, for example, polyol compounds of polyester-type or polyether-type, etc., react with a polyisocianate compound, such as 2,4-tolylene diisocyanate, 2,6-tolylene diisocyanate, 1,3-xylylene diisocyanate, 1,4-xylylene diisocyanate and diphenylmethane 4,4-diisocyanate,) is brought to react with acrylate having a hydroxyl group or methacrylate, (such as 2-hydroxyethyl acrylate, 2-hydroxylethyl methacrylate, 2-hydroxypropyl acrylate, 2-hydroxypropyl methacrylate, polyethylene glycol acrylate and polyethylene glycol methacrylate,) may be mentioned.

In the case of using a urethane acrylate-type oligomer as a reactive oligomer, particularly, when using those having a molecular weight of preferably 300 or higher; more preferably 1000 or higher and preferably 30000 or lower and more preferably 8000 or lower, it is possible to prevent an adhesive from remaining on an object even if the object is rough. Note that a value of a molecular weight is obtained as a weight-average molecular weight (Mw) in terms of polystyrene using a mobile phase solvent, such as tetrahydrofuran. Function group number of a urethane acrylate-type oligomer is preferably exceeding 6 from a viewpoint of preventing a coat film from coming off.

Products available on market may be used for the compounds above. For example, U-15HA, UA-32P and U-324A, etc. of the product name of NK Oligo Series made by Shin-Nakamura Chemical Co., Ltd. and V-4000BA, etc. of the product name of UNIDIC Series made by DIC Corporation may be mentioned.

Also, it is preferable that an adhesive layer contains polyisocyanate, alkyl etherified melamine compound or other curing agent and a polymerization initiator, etc.

A thickness of the adhesive layer varies depending on a kind of an adhesive, but preferably 0.5 μm or more, more preferably 2 μm or more and preferably 10 μm or less. When the thickness of the adhesive layer is 0.5 μm or more, adhesiveness between a shrinkable film and a non-shrinkable film after heating becomes preferable. On the other hand, when it is 10 μm or less, release from an object after heating becomes easy. Note that when the thickness of the adhesive film is too thick, the adhesive layer and non-shrinkable film cannot follow the shrinkable film properly when the shrinkable film shrinks when heated and it is liable that it becomes impossible to easily peel the whole easily releasable adhesive film from an object.

A non-shrinkable film used in the present invention is to bring about a reaction force against a shrink force when a shrinkable film shrinks by heating and functions to generate a couple of force for releasing the easily releasable adhesive film easily from the object. By placing the non-shrinkable film between a shrinkable film and an easily releasable adhesive film, it becomes possible to peel off the easily releasable adhesive film including an easily releasable adhesive layer easily without leaving any adhesive of the easily releasable adhesive layer on the object.

The non-shrinkable film used in the present invention is not particularly limited as long as it is a film which does not shrink when heated (namely, thermally non shrinkable). In the present embodiment, “thermally non shrinkable” means that a shrinkage (explained above) calculated based on a size change before and after heating the non-shrinkable film at 120° C. is preferably less than 10% and more preferably 5% or less in all of the main shrink direction and other directions than that (both explained above).

As a non-shrinkable film as such, for example, plastic films of polyethylene naphthalate, polycarbonate, polyethylene, polypropylene, polybutene, polymethyl pentene, polyethylene terephthalate, polybutylene terephthalate, polybutadiene, polyurethane, polystyrene, triacetyl cellulose, acryl, polyvinyl chloride and nobornene compound may be mentioned. Also, a polymer film containing a compound having a carboxyl group as a building block of the polymer or a multilayer body of this and a general-purpose polymer film may be used, as well. The non-shrinkable film may be a single layer product or a multilayer product formed by a plurality of layers. As a multilayer product, other than a multilayer product of non-shrinkable films, a multilayer product including the shrinkable film above may be used as long as a shrinkage of the entire multilayer product can be adjusted to the range explained above.

In the present embodiment, as a non-shrinkable film, those having a shrinkage being different from a shrinkage of the shrinkable film by preferably 50% or more are selected to be used preferably. By using a non-shrinkable film having a shrinkage being different from that of the shrinkable film by 50% or more, the effect of peeling off the entire easily releasable adhesive film after heating is furthermore improved, and an advantage that a releasable property would be improved furthermore can be expected.

A thickness of the non-shrinkable film is not particularly limited, however, when it is too thin, the handleability becomes poor, while when too thick, it cannot follow the shrink film when the shrink film shrinks by heating and it becomes impossible to peel the entire easily releasable adhesive layer off from an object. From that viewpoint, 2 to 300 μm is preferable and 10 to 125 μm is more preferable.

A surface of the non-shrinkable film may be subjected to the same surface treatments as in the shrinkable film explained above so as to improve adhesiveness to a contacting layer and to distinguish existence of adhered easily releasable adhesive film.

Note that a different point between the shrinkable film and non-shrinkable film used in the present invention is their different shrinkages. For example, when manufacturing a polyethylene terephthalate film, it is possible to manufacture two kinds of polyethylene terephthalate films having different shrinkages by setting the manufacture condition, etc. arbitrarily.

The easily releasable adhesive layer used in the present invention has an adhesive force before heating but the adhesive force declines after heating. As a result that such an easily releasable adhesive layer is provided to the side to be bonded to an object of an easily releasable adhesive film, when heat is applied to the easily releasable adhesive film, shrink of a shrink film makes the easily releasable adhesive film curled to be convex to the object, so that a contact area with the object decreases. In addition, due to a decline of the adhesive force of the easily releasable adhesive layer itself after heating, an adhesive force between the easily releasable adhesive film and the object declines remarkably. Thereby, it becomes possible to release the easily releasable adhesive film easily together with the entire easily releasable adhesive layer.

As an easily releasable adhesive layer as such, as long as it exhibits a function of decreasing an adhesive force by heating, a material thereof is not particularly limited. For example, (1) it can be configured by a “thermally foamable release type” material by using as an adhesive thermally expandable particles, which form foams and/or expand by heating, the thermally expandable particles expand by heating so as to decrease a contact area with an object and decline an adhesive force. Alternatively, (2) it may be configured by a “thermosetting release type” material, which decreases an adhesive force to an object by a polymerization reaction of the reactive oligomer caused by heating.

When the easily releasable adhesive layer used in the present invention is configured by (1) the thermally foamable release type above, it is necessary to foam and/or expand thermally expandable particles so as to decrease the adhesive force, however, if a particle diameter of the thermally expandable particles do not have a certain size, it is liable that the effect cannot be brought effectively. Also, to prevent dropping off of thermally expandable particles having a large particle diameter, a coating has to have a certain thickness. On the other hand, those configured by (2) the thermosetting release type material above do not have any restriction on a coating thickness thereof, and the coating thickness can be made thin. Thereby, an easily releasable adhesive film as a whole can be made thin, so that it becomes possible to improve accuracy in processing an object, such as silicon wafers, made to be thinner and smaller in recent years, to which the film is bonded.

Note that as an adhesive layer to bring about an easily releasable property, as shown in the patent document 1, (3) it may be considered to configure it by an “energy ray irradiation release type” material, which decreases the adhesive force by irradiation of an energy ray by using an energy ray curing type resin. However, when using an easily releasable adhesive film using such an energy ray irradiation release type easily releasable adhesive layer, the energy ray has to reach the easily releasable adhesive layer. Therefore, a shrinkable film and non-shrinkable film as base materials have to be designed to be transparent. Also, with those configured by an energy ray curing type resin, the adhesive force does not decrease and it becomes difficult to easily release an object made to be thin and compact, therefore, it is not preferable.

As a thermally Learnable release type easily releasable adhesive layer, those configured by an adhesive for giving adhesiveness and thermally expandable particles (micro capsules) for giving thermally expanding property may be mentioned. As an adhesive, those listed as an adhesive to configure the adhesive layer explained above may be used. The adhesive may contain, in addition to an adhesive component (base polymer), suitable additives, such as a crosslinking agent (for example, polyisocyanate, alkyl etherized melamine compound, etc.), an adhesiveness giving agent (for example, a rosin derivative resin, polyterpene resin, petroleum resin and oil soluble phenol resin, etc.), a plasticizer, filler and antioxidant, etc. arbitrarily.

As thermally expandable particles, a material which easily becomes a gas and expands by heating, such as isobutene, propane and pentane, made to be fine particles contained in a shell having elasticity may be used. The shell is often formed by a thermofusion material and a material to be broken due to the thermal expansion. As a material for forming the shell, for example, vinylidene chloride-acrylonitryl copolymer, polyvinyl alcohol, polyvinyl butylal, polymethyl methacrylate, polyacrylonitryl, polyvinylidene chloride, polyslufone, etc., may be mentioned. Thermally expandable fine balls may be manufactured by a generally used method, such as a coacervation method and a boundary surface polymerization method. Note that as the thermally expandable fine balls, products available on market, such as micro sphere (product name, made by Matsumoto Yushi-Seiyaku co., ltd.) may be used, as well.

To decrease the adhesive force of the easily releasable adhesive layer effectively by a thermal treatment, thermally expandable fine balls having an appropriate strength of not to burst until the coefficient of volume expansion becomes 5 times or more, specially 7 times or more and particularly 10 times or more.

A blending amount of the thermally expansion particles may be set arbitrarily in accordance with a coefficient of expansion of the easily releasable adhesive layer and a decreasing property of the adhesive force, but it is normally, for example, 1 to 150 parts by weight, preferably 10 to 130 parts by weight and furthermore preferably 20 to 100 parts by weight with respect to 100 parts by weight of an adhesive for forming the easily releasable adhesive layer.

A size of the thermally expansion particles varies in accordance with a thickness of the easily releasable adhesive layer, so that it cannot be said generally. However, in terms of obtaining initial (a state before applying heat) adhesiveness and obtaining preferable releasable property from an electronic device after heating, preferably the average particle diameter as the lower limit is 1.5 μm or more, furthermore 4 μm or more and as the upper limit, less than 15 μm and furthermore less than 10 μm. Also, an average particle diameter of the thermally expandable particles is preferably 60 to 90% and furthermore 70 to 80% of a thickness of the easily releasable adhesive layer.

As to a thickness of the thermally foamable release type easily releasable adhesive layer, the lower limit is 2 μm or more, preferably 5 μm or more and the upper limit is less than 20 μm and preferably 15 μm or less. When the thickness is too thick, the easily releasable adhesive layer moves due to a pressure at the time of dicing, precision of electronic devices after dicing is deteriorated and the production yields declines. On the other hand, when the thickness is too thin, thermally expandable particles to be added become excessively small, and it is liable that a deformation degree of the easily releasable adhesive layer after heating becomes small and the adhesive force (stickiness) becomes hard to be decreased.

As the thermosetting release type easily releasable adhesive layer of (2) above, those containing an adhesive and a reactive oligomer may be mentioned. As an adhesive, those listed as an adhesive for configuring the adhesive layer explained above may be used. Among those, it is preferable to use acryl-type adhesives. Also, the easily releasable adhesive layer may contain, in addition to an adhesiveness component (base polymer), suitable additives, such as a curing agent (for example, polyisocyanate, alkyl etherized melamine compound, etc.), an adhesiveness giving agent (for example, rosin derivative resin, polyterpene resin, petroleum resin and oil-soluble phenol resin, etc.), a polymerization initiator, a plasticizer, filler and antioxidant, etc. As a reactive oligomer, those listed as a reactive oligomer for configuring the adhesive layer may be mentioned.

As a thickness of the thermosetting release type easily releasable adhesive layer, the lower limit is preferably 2 μm or more and preferably 5 μm or more and the upper limit is less than 15 μm and preferably less than 10 μm. When the thickness is less than 15 μm, it becomes possible to perform accurate dicing on an object, such as silicon wafers, made to be thinner and more compact in recent years. On the other hand, when the thickness is 2 μm or more, a decline of an initial adhesiveness can be prevented.

Also, the easily releasable adhesive film of the present invention is preferably provided with a separator on a surface of the easily releasable adhesive layer so as to improve the handleability. Such a separator is not particularly limited and, for example, plastic films of a polyethylene laminate paper, polypropylene, polyethylene, polyester, polycarbonate, triacetyl cellulose, polyvinyl chloride, acryl, polystyrene, polyamide, polyimide and vinylidene chloride-vinyl chloride copolymer, and those plastic films with one surface thereof subjected to a mold release treatment, etc. may be mentioned.

A thickness of the separator is not particularly limited but those with 10 μm to 250 μm and preferably 20 μm to 125 μm are generally used.

The easily releasable adhesive film of the present invention may be configured to have another adhesive layer (second adhesive layer) between the non-shrinkable film and the easily releasable adhesive layer explained above. By providing the second adhesive layer, adhesiveness between the non-shrinkable film and the easily releasable adhesive layer can be improved comparing with that in the case without it.

An adhesive agent to be used in the second adhesive layer as such is not particularly limited and the same adhesives as in the easily releasable adhesive layer explained above may be used.

As to a thickness of the second adhesive layer, the lower limit is 1 μm or more and preferably 3 μm or more and the upper limit is less than 20 μm and preferably less than 10 μm. When the thickness is too thick, as same as in the easily releasable adhesive layer explained above, the second adhesive layer moves due to a pressure at the time of processing, accuracy of electronic devices after processing becomes poor and the yields decline. While when the thickness is too thin, it is hard to obtain the effect of improving adhesiveness with the non-shrinkable film.

Regarding an adhesive force of the easily releasable adhesive film of the present invention against an object before heating, it is preferable that an adhesive force based on the 180-degree release test in JIS Z0237:2000 is 2 to 10N/25 mm, and more preferably 3 to 7N/25 mm. Note that the release speed here is 300 mm/min.

As a method of producing the easily releasable adhesive film of the present invention as explained above, for example, materials for configuring the easily releasable adhesive layer as explained above are mixed to prepare an easily releasable adhesive layer application liquid, it is applied on the non-shrinkable film explained above by a conventionally well-known coating method, such as a bar coater, die coater, blade coater, spin coater, roll coater, gravure coater, flow coater, spray and screen printing, and then the result is dried in accordance with need so as to be bonded with the separator explained above.

Next, on the other surface of the non-shrinkable film explained above, the adhesive and reactive oligomer explained above, diluting solvent and additives are mixed to prepare an adhesive layer application liquid and applied by a conventionally well-known coating method in the same way as above, then, the result is dried in accordance with need to be bonded with the shrinkable film explained above, aging (for example, at 23° C. for 7 days) is performed thereon in accordance with need, so that the easily releasable adhesive film of the present invention can be obtained.

Also, for example, on one surface of the non-shrinkable film explained above, an adhesive layer is formed in the same way as above, and a surface of the obtained adhesive layer is bonded with a shrinkable film so as to produce a substrate film.

Next, an easily releasable adhesive layer is formed in the same way as explained above on the separator explained above, then, an adhesive layer application liquid is prepared by mixing the adhesive explained above with, in accordance with need, a diluting solvent and additives and applied to the easily releasable adhesive layer, and dried so as to form an adhesive layer on the easily releasable adhesive layer. A surface of the obtained adhesive layer is bonded with the non-shrinkable film of the substrate film produced as above and aging is performed in the same way as above, so that the easily releasable adhesive film of the present invention can be obtained.

Note that, in the explanation above, an example of a production method of the easily releasable adhesive film of the present invention was explained but the present invention is not limited to this. For example, it may be also produced by forming on a separator an easily releasable adhesive layer, (an adhesive layer as needed), a non-shrinkable film and an adhesive layer in this order and bonding it with a shrinkable film.

As explained above, since the easily releasable adhesive film of the present invention is configured by combining an adhesive layer containing a reactive oligomer in a specific amount and a shrinkable film (preferably, a shrinkage in a predetermined temperature range is adjusted to be a specific value), only by adding heat to an object after finishing processing, it can be released easily from the object and, furthermore, it does not deform or damage the object. Therefore, the easily releasable adhesive film of the present invention can be suitably used as a temporary fixing sheet for a variety of processing (dicing and polishing, etc.) on semiconductor materials (silicon wafers and glass wafers, etc. which have been made to be thinner and downsized particularly in recent years) as the object.

### EXAMPLES

Below, present invention will be explained furthermore in detail with examples. Note that “part” and “%” in the examples are based on weight unless otherwise mentioned.

### 1. Producing Easily Releasable Adhesive Film

### Example 1

On one surface of a non-shrikable film (shrinkage ratio at 120° C. was less than 10%, thickness was 38 μm, polyethylene naphthalate film, COSMOSHINE A4300: TOYOBO Co., Ltd.), an easily releasable adhesive layer application liquid as prescribed below is applied by a bar coater method, dried to form an easily releasable adhesive layer having a thickness of 7 μm and it was bonded with a mold release treatment surface of a separator (thickness was 25 μm, polyethylene naphthalate film, MRF: Mitsubishi Chemical Polyester Film Co., Ltd.).

### <Prescription of Easily Releasable Adhesive Film Application Liquid of Example 1>

| | |
|---|---|
| acryl-type adhesive | 57.1 parts |
| (SK dine SW-2B: Soken Chemical Engineering Co., Ltd. | |
| Solid Content 35%) | |
| urethane acrylate-type oligomer | 20 parts |
| (NK Oligo U15HA: Shin-Nakamura Chemical Co., Ltd., | |
| 45000 mPa · s/40° C., average molecular weight 2300, | |
| functional group number 15, solid content 100%) | |
| polymerization initiator | 4 parts |
| (OTAZO-15: Otsuka Chemical Co., Ltd., solid content 100%) | |
| Curing Agent (polyisocyanate) | 5 parts |
| (Colonate L45E: Nippon Polyurethane Industry Co., Ltd., | |
| solid content 45%) | |
| Ethyl acetate | 57.5 parts |
| methylethyl Ketone | 57.5 parts |

Next, on a surface with no easily releasable adhesive layer formed thereon of a non-shrinkable film, an adhesive layer application liquid prescribed as below was applied by a bar-coater method and dried to form an adhesive layer having a thickness of 5 μm, and it was bonded with a thermally shrinkable film (a thermal shrinkage ratio at 120° C. is 70% or greater, thickness is 50 μm, polyethylene naphthalate film, SPACECLEAN S7561: TOYOBO Co., Ltd.), so that an easily releasable adhesive film of the example 1 was produced.

### <Prescription of Adhesive Film Application Liquid of Example 1>

| | | |
|---|---|---|
| polyurethane-type adhesive | 85 | parts |
| (TakeLuck A971: Mitsubishi Chemical, Inc. Solid Content | | |
| 50%) | | |
| urethane acrylate-type oligomer | 15 | parts |
| (NK Oligo U15HA: Shin-Nakamura Chemical Co., Ltd., | | |
| solid content is adjusted to 50% by using methylethyl | | |
| ketone) | | |
| polymerization initiator | 0.23 | part |
| (OTAZO-15: Otsuka Chemical Co., Ltd., solid content | | |
| 100%) | | |
| Curing agent (polyisocyanate) | 9.7 | parts |
| (Takenate D110N: Mitsubishi Chemical, Inc. Solid Content | | |
| 60%) | | |
| toluene | 57 | parts |
| methylethyl ketone | 57 | parts |

### Example 2

Other than changing the polyurethane-type adhesive in the adhesive layer application liquid of the example 1 to 70 parts by weight, the urethane acrylate-type oligomer to 30 parts by weight and the polymerization initiator to 0.45 part by weight, in the same way as in the example 1, an easily releasable adhesive film of an example 2 was produced.

### Example 3

Other than changing the polyurethane-type adhesive in the adhesive layer application liquid of the example 1 to 60 parts by weight, the urethane acrylate-type oligomer to 40 parts by weight and the polymerization initiator to 0.6 part by weight, in the same way as in the example 1, an easily releasable adhesive film of an example 3 was produced.

### Example 4

Other than changing the polyurethane-type adhesive in the adhesive layer application liquid of the example 1 to 50 parts by weight, the urethane acrylate-type oligomer to 50 parts by weight and the polymerization initiator to 0.75 part by weight, in the same way as in the example 1, an easily releasable adhesive film of an example 4 was produced.

### Comparative Example 1

Other than changing the polyurethane-type adhesive, in the adhesive layer application liquid of the example 1 to 100 parts by weight and omitting the urethane acrylate-type oligomer and the polymerization initiator, in the same way as in the example 1, an easily releasable adhesive film of a comparative example 1 was produced.

### Comparative Example 2

Other than changing the polyurethane-type adhesive, in the adhesive layer application liquid of the example 1 to 91 parts by weight, the urethane acrylate-type oligomer to 9 parts by weight and the polymerization initiator to 0.14 part by weight, in the same way as in the example 1, an easily releasable adhesive film of a comparative example 2 was produced.

### Comparative Example 3

Other than changing the polyurethane-type adhesive in the adhesive layer application liquid of the example 1 to 40 parts by weight, the urethane acrylate-type oligomer to 60 parts by weight and the polymerization initiator to 0.9 part by weight, in the same way as in the example 1, an easily releasable adhesive film of a comparative example 3 was produced.

### Comparative Example 4

Other than changing the polyurethane-type adhesive in the adhesive layer application liquid of the example 1 to 30 parts by weight, the urethane acrylate-type oligomer to 70 parts by weight and the polymerization initiator to 1.05 parts by weight, in the same way as in the example 1, an easily releasable adhesive film of a comparative example 4 was produced.

### 2. Evaluation

### (1) Adhesive Force Before Heating

From an easily releasable adhesive film of each example, a separator was released so as to make the easily releasable adhesive layer exposed and a glass wafer was bonded to be fixed thereon. Then, on the easily releasable adhesive film, a 180° peel test was conducted on the easily releasable adhesive film side by using a TENSILON Universal Tensile Testing Machine (TENSILON HTM-100: Orientec Co., Ltd.) based on JIS Z0237:2000. The test piece was 25 mm in width. The measurement results are shown in Table 1.

### (2) Releasable Property After Heating

In the same way as in (1), a separator was released from an easily releasable adhesive film of each example so as to make the easily releasable adhesive layer exposed and a glass wafer was bonded to be fixed thereon. Then, the easily releasable adhesive film together with the glass wafer was put in an oven at 100° C. for 5 minutes to perform a thermal treatment. As a result of heating, those which exhibited that the easily releasable adhesive film curled to be convex to the glass wafer and started to come off from end portions of the adhesive portion, so that a contact area with the glass wafer becomes small and released naturally from the glass wafer were evaluated “⊚”; those which did not released naturally from the glass wafer but released easily when shaken were evaluated as “◯”, those which did not released easily because the easily releasable adhesive film did not curl properly were evaluated as “×”, those did not work as an easily releasable adhesive film because the easily releasable adhesive film was detached at a boundary surface of the adhesive layer and non-shrinkable film when heated were evaluated as “−”. The measurement results are shown in Table 1.

TABLE 1

| | Reactive | Adhesive | |
|---|---|---|---|
| | Oligomer | Force Before | Releasable |
| | Content (part | Heating | Property |
| | by weight) | (N/25 mm) | after Heating |
| Example 1 | 17.6 | 4.75 | ◯ |
| Example 2 | 42.9 | 4.75 | ⊚ |
| Example 3 | 66.7 | 4.75 | ⊚ |
| Example 4 | 100 | 4.75 | ◯ |
| Comparative | 0 | 4.75 | X |
| Example 1 | | | |
| Comparative | 9.9 | 4.75 | X |
| Example 2 | | | |
| Comparative | 150 | 4.75 | — |
| Example 3 | | | |
| Comparative | 223 | 4.75 | — |
| Example 4 | | | |

In Table, “Reactive Oligomer Content” indicates a content (part by weight) of a reactive oligomer with respect to 100 parts by weight of adhesive in the adhesive layer.

The followings can be understood from the results in Table 1. The easily releasable adhesive films in the examples 1 to 4 had a sufficient adhesive force before heating, however, they were released easily from a glass wafer after heating.

Particularly, the easily releasable adhesive films in the examples 2 and 3 were naturally released from the glass wafer after heating without any work of pulling with a hand, which was extremely easy. The reason why they obtained notable evaluation is considered that a reactive oligomer amounts in the adhesive layers were appropriate comparing with the examples 1 and 4.

On the other hand, the easily releasable adhesive film in the comparative example 1 did not contain any reactive oligomer in the adhesive layer. Therefore, an adhesive force before heating was preferable, but the adhesive layer hindered a shrink effect of the shrinkable film after heating and the easily releasable adhesive film did not curl to be convex to the glass wafer properly. Thereby, release of the easily releasable adhesive film from the glass wafer became not easy.

Also, the easily releasable adhesive film in the comparative example 2 contained a reactive oligomer in addition to an adhesive in the adhesive layer, wherein a content of the reactive oligomer in the adhesive layer was less than 12 parts by weight with respect to 100 parts by weight of the adhesive. Therefore, the adhesive film hindered a shrink effect of the shrinkable film after heating, and the easily releasable adhesive film did not curl to be convex to the glass wafer properly. As a result, release of the easily releasable adhesive film from the glass wafer became not easy.

Also, in the easily releasable adhesive film in the comparative examples 3, a content of a reactive oligomer in the adhesive layers exceeded 130 parts by weight with respect to 100 parts by weight of an adhesive. Therefore, when heating the easily releasable adhesive film, an adhesive force of the adhesive layer to the non-shrinkable film became insufficient. Due to this, when the easily releasable adhesive film was released from the glass wafer after heating, there arose detachment on the boundary surface of the adhesive layer and the non-shrinkable film. As a result, they could not function as an easily releasable adhesive film.

### Example 5

As an urethane acrylate-type oligomer, other than using the product name of UA-32P (made by Shin-Nakamura Chemical Co., Ltd., average molecular weight 1560, functional group number 9) instead of the product name of U15HA, an adhesive layer application liquid of the same prescription as that in the example 1 was prepared. After that, an easily releasable adhesive film was produced in the same way as in the example 1. The same evaluation was made and the same evaluation as that in the example 1 was obtained.

1. An easily releasable adhesive film, characterized by being configuring by laminating a first film that is thermally shrinkable, an adhesive layer that contains a reactive oligomer together with an adhesive, a second film that is not thermally shrinkable, and an easily releasable adhesive layer in this order: wherein
the reactive oligomer is contained in an amount of 12 parts by weight or more and 130 parts by weight or less in the adhesive layer with respect to 100 parts by weight of the adhesive.

2. The adhesive film according to claim 1, wherein the adhesive layer has a thickness of 0.5 μm or more and 10 μm or less.

3. The adhesive film according to claim 1, wherein the easily releasable adhesive layer is configured by a thermosetting and releasable-type easily releasable adhesive layer containing a reactive oligomer together with an adhesive.

4. The adhesive film according to claim 1, wherein at least an urethane acrylate type oligomer is contained as the reactive oligomer.

5. The adhesive film according to claim 1, wherein the first film has a shrinkage of 50% or greater and 90% or less in a main shrink direction at 120° C.

6. A temporary fixing sheet configured by the adhesive film according to claim 1 and to be bonded to an object when processing the object.

7. The adhesive film according to claim 2, wherein the easily releasable adhesive layer is configured by a thermosetting and releasable-type easily releasable adhesive layer containing a reactive oligomer together with an adhesive.

8. The adhesive film according to claim 2, wherein at least an urethane acrylate type oligomer is contained as the reactive oligomer.

9. The adhesive film according to claim 3, wherein at least an urethane acrylate type oligomer is contained as the reactive oligomer.

10. The adhesive film according to claim 2, wherein the first film has a shrinkage of 50% or greater and 90% or less in a main shrink direction at 120° C.

11. The adhesive film according to claim 3, wherein the first film has a shrinkage of 50% or greater and 90% or less in a main shrink direction at 120° C.

12. The adhesive film according to claim 4, wherein the first film has a shrinkage of 50% or greater and 90% or less in a main shrink direction at 120° C.

13. A temporary fixing sheet configured by the adhesive film according to claim 2 and to be bonded to an object when processing the object.

14. A temporary fixing sheet configured by the adhesive film according to claim 3 and to be bonded to an object when processing the object.

15. A temporary fixing sheet configured by the adhesive film according to claim 4 and to be bonded to an object when processing the object.

16. A temporary fixing sheet configured by the adhesive film according to claim 5 and to be bonded to an object when processing the object.
